(19) United States
(12) Patent Application Publication
(10) Pub. No.: US 2026/0129824 A1
(43) Pub. Date: May 7, 2026

(54) SEMICONDUCTOR STRUCTURE AND FABRICATION METHOD THEREFOR

(71) Applicant: CXMT Corporation, Hefei City (CN)

(72) Inventors: Hong WANG, Hefei City (CN); Guoliang WAN, Hefei City (CN); Xiaojie LI, Hefei City (CN)

(73) Assignee: CXMT Corporation, Hefei City (CN)

(21) Appl. No.: 19/260,370

(22) Filed: Jul. 4, 2025

Related U.S. Application Data
(63) Continuation of application No. PCT/CN2025/077782, filed on Feb. 18, 2025.

(30) Foreign Application Priority Data
Nov. 4, 2024 (CN) 202411571317.0

(51) Int. Cl. H10B 12/00

(52) U.S. Cl. CPC H10B 12/30; H10B 12/05

(57) ABSTRACT

A semiconductor structure and a fabrication method therefor are provided. The semiconductor structure includes: multiple stacked substructures located on a substrate; word line layers; a first word line isolation structure; and a second word line isolation structure, where the second word line isolation structure includes a first isolation portion, a second isolation portion, and a third isolation portion that are sequentially connected, the first isolation portion and the third isolation portion extend in the vertical direction, the second isolation portion extends in a second direction and connects the bottom of the first isolation portion and the bottom of the third isolation portion, and the bottom end of each of the word line layers is connected to the top of the second isolation portion. The foregoing semiconductor structure can improve the reliability of the semiconductor structure.

### CROSS-REFERENCE TO RELATED APPLICATIONS

The present disclosure is a continuation of International Application No. PCT/CN2025/077782 filed on Feb. 18, 2025, which claims priority to Chinese Patent Application No. 202411571317.0 filed on Nov. 4, 2024. The disclosures of the above-referenced applications are hereby incorporated by reference in their entirety.

### BACKGROUND

The development of dynamic random access memory (DRAM) targets performance indicators such as high speed, high integration density, and low power consumption. With the miniaturization of semiconductor device structure sizes, technical barriers encountered by existing structures become increasingly obvious. Therefore, developing more novel structures based on the existing structures is an advantageous means to break existing technical barriers.

The emergence of three-dimensional dynamic random access memory (3D DRAM), in particular, 3D DRAM incorporating a multilayer horizontal cell (MHC), which usually includes multiple transistors stacked on a substrate, meets the foregoing requirements.

However, in a procedure of forming a vertical wire (e.g., a word line) in the three-dimensional dynamic random access memory, due to a limitation of a dry etching process, a short circuit problem of the wire caused by a residual conductive material is prone to occur. Consequently, the reliability of the memory is reduced.

### SUMMARY

Embodiments of the present disclosure relate to the field of semiconductor technologies, and in particular, to a semiconductor structure and a fabrication method therefor.

According to a first aspect of the embodiments of the present disclosure, a semiconductor structure is provided, including: multiple stacked substructures located on the substrate, where the multiple stacked substructures are arranged at intervals in a first direction, and each of the stacked substructures includes active layers and first dielectric layers that are alternately stacked in the vertical direction; word line layers, where each of the word line layers is located on the top surface of each of the stacked substructures and sidewalls thereof perpendicular to the first direction, and the bottom end of each of the word line layers is lower than the bottom surface of each of the stacked substructures; a first word line isolation structure, where the first word line isolation structure is located between the stacked substructures; and a second word line isolation structure, where the second word line isolation structure includes a first isolation portion, a second isolation portion, and a third isolation portion that are sequentially connected, the first isolation portion and the third isolation portion extend in the vertical direction, the second isolation portion extends in a second direction and connects the bottom of the first isolation portion and the bottom of the third isolation portion, and the bottom end of each of the word line layers is connected to the top of the second isolation portion.

In some embodiments, the substrate includes protrusion portions located under the stacked substructures, the second isolation portion is located between the protrusion portions, and the top surface of the second isolation portion is lower than the top surface of each of the protrusion portions.

In some embodiments, the semiconductor structure further includes: a gate dielectric layer, where the gate dielectric layer covers a sidewall of each of the active layers perpendicular to the first direction; and a substrate protective layer, where the substrate protective layer covers sidewalls and the bottom of a groove formed between adjacent ones of the protrusion portions, and the substrate protective layer is sandwiched between the second isolation portion and the substrate; where the thickness of the substrate protective layer is greater than the thickness of the gate dielectric layer, and the ratio of the thickness of the substrate protective layer to the thickness of each of the first dielectric layers ranges from 0.5 to 0.6.

In some embodiments, the width of the first word line isolation structure in the second direction is equal to the width of each of the word line layers in the second direction, and the width of the second word line isolation structure in the second direction is equal to the width of the each of stacked substructures in the second direction.

In some embodiments, the width of the first word line isolation structure in the first direction is equal to a spacing of adjacent ones of the word line layers in the first direction, and the width of the second word line isolation structure in the first direction is equal to a spacing of adjacent ones of the stacked substructures in the first direction.

In some embodiments, each of the word line layers is in an inverted U-shaped morphology in a cross section in the first direction and the vertical direction.

In some embodiments, each of the word line layers comprises a first word line portion, a second word line portion, and a third word line portion that are sequentially connected, each of the first word line portion and the third word line portion is located on a sidewall of each of the stacked substructures perpendicular to the first direction, the second word line portion connects a top of the first word line portion and a top of the third word line portion, and the second word line portion is located on the top surface of each of the stacked substructures.

In some embodiments, materials of the substrate protective layer and the first dielectric layers are the same, and a thickness of each of the first dielectric layers in the vertical direction is at most twice a thickness of the substrate protective layer in the vertical direction.

According to a second aspect of the embodiments of the present disclosure, a fabrication method for a semiconductor structure is provided, including the steps as follows. Multiple stacked substructures located on a substrate are formed, where the multiple stacked substructures are arranged in a first direction, and each of the stacked substructures includes active layers and first dielectric layers that are alternately stacked in the vertical direction; a sacrificial structure located between the stacked substructures is formed; a word line material layer and a first word line isolation structure are formed, where the word line material layer is located on the top surface of each of the stacked substructures, sidewalls thereof perpendicular to the first direction, and a part of the surface of the sacrificial structure, and the first word line isolation structure is located between the stacked substructures; the sacrificial structure is removed to form a communication trench; a part of the word line material layer exposed by the communication trench are removed to form word line layers, where each of the word line layers is located on the top surface of each of the stacked substructures and sidewalls thereof perpendicular to the first direction, and the bottom end of each of the word line layers is lower than the bottom surface of each of the stacked substructures; and a second word line isolation structure filling the communication trench is formed, where the second word line isolation structure includes a first isolation portion, a second isolation portion, and a third isolation portion that are sequentially connected, the first isolation portion and the third isolation portion extend in the vertical direction, the second isolation portion extends in a second direction and connects the bottom of the first isolation portion and the bottom of the third isolation portion, and the bottom end of each of the word line layers is connected to the top of the second isolation portion.

In some embodiments, that stacked substructures located on a substrate are formed includes the steps as follows. Stacked structures located on the substrate are formed, where each of the stacked structures includes first semiconductor layers and second semiconductor layers that are alternately stacked; a part of the stacked structures and the substrate are removed to form multiple first through-holes and patterned stacked structures, where the multiple first through-holes are arranged in the first direction and run through the stacked structures, and each of the patterned stacked structures is located between the first through-holes; a part of the first semiconductor layers are removed through lateral etching along the first through-holes to form first gap trenches, where the first gap trenches are in communication with the multiple first through-holes; and first dielectric layers are deposited to form the stacked substructures, where the first dielectric layers fill the first gap trenches and cover sidewalls of the multiple first through-holes.

In some embodiments, that a sacrificial structure located between the stacked substructures is formed includes the steps as follows. Vertical sacrificial portions filling the multiple first through-holes are formed; and a part of each of the vertical sacrificial portions are removed to form the sacrificial structure, where the sacrificial structure includes a first sacrificial portion, a second sacrificial portion, and a third sacrificial portion that are sequentially connected, the first sacrificial portion and the third sacrificial portion extend in the vertical direction, the second sacrificial portion extends in the second direction and connects the bottom of the first sacrificial portion and the bottom of the third sacrificial portion, and the top surface of the second sacrificial portion is lower than the bottom surface of each of the stacked substructures.

In some embodiments, a word line trench is enclosed by the first sacrificial portion, the second sacrificial portion, and the third sacrificial portion; and that a word line material layer and a first word line isolation structure are formed includes the steps as follows. A part of the first dielectric layers that are located on sidewalls of the first through-holes and that are exposed by the word line trench are removed; a gate dielectric layer is formed on a sidewall of each of the active layers exposed by the word line trench; and the word line material layers conformally covering an inner wall of the word line trench is formed, and the first word line isolation structure is filled.

In some embodiments, that the sacrificial structure is removed includes the steps as follows. Planarization processing is performed to expose the top surface of the first sacrificial portion and the top surface of the third sacrificial portion; and the first sacrificial portion, the second sacrificial portion, and the third sacrificial portion are removed by adopting a wet etching process.

In the embodiments of the present disclosure, each of the word line layers is adopted as a whole to cover the top surface and the sidewall of each of the stacked substructures. This can ensure interconnection between two word line layer parts corresponding to the same transistor, and avoid an open circuit of the word line layers. In addition, the bottoms of the adjacent ones of the word line layers are disconnected, and two parts of the first word line isolation structure and the second word line isolation structure are adopted together to isolate the adjacent ones of the word line layers, so that a short circuit between the word line layers can be avoided, and coupling between the word line layers can be effectively reduced, thereby improving the reliability of the semiconductor structure.

### BRIEF DESCRIPTION OF DRAWINGS

To describe the technical solutions in the embodiments of the present disclosure or the conventional technologies more clearly, the following briefly describes the accompanying drawings required for describing the embodiments or the conventional technologies. Clearly, the accompanying drawings in the following description show merely some embodiments of the present disclosure, and a person of ordinary skill in the art may still derive other accompanying drawings from these accompanying drawings without creative efforts.

FIG. 1 is a three-dimensional schematic diagram of a part of a semiconductor structure according to an example embodiment;

FIG. 2 is a flowchart of a fabrication method for a semiconductor structure according to an embodiment of the present disclosure; and

FIG. 3A to FIG. 13B are schematic top views and schematic cross-sectional views of a semiconductor structure in a fabrication procedure according to an embodiment of the present disclosure, where FIG. 3A, FIG. 4A, FIG. 5A, FIG. 6A, FIG. 7A, FIG. 8A, FIG. FIG. 9A, FIG. 10A, FIG. 11A, FIG. 12A and FIG. 13A are schematic top views of the semiconductor structure, and FIG. 3B, FIG. 4B, FIG. 5B, FIG. 6B, FIG. 7B, FIG. 8B, FIG. 9B, FIG. 10B, FIG. 11B, FIG. 12B and FIG. 13B are schematic cross-sectional views of the semiconductor structure.

### DETAILED DESCRIPTION

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily describe a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

In a semiconductor structure, a three-dimensional dynamic random access memory is taken as an example, and an architecture in which memory cells stacked in the vertical direction is adopted, where the memory cells include transistors and capacitors arranged in the horizontal direction, thereby improving the degree of integration of the dynamic random access memory. In a procedure of forming word lines, an etching process is usually adopted after one-step deposition to disconnect adjacent word lines through etching. However, with an increase in the degree of integration of the semiconductor structure, it is more difficult to etch the word lines with a high aspect ratio through dry etching. For example, a short circuit problem of the word lines caused by a residue of a word line conductive material is prone to occur. If the radio frequency power of a plasma is increased, it is easy to cause damage to the word lines. Consequently, the reliability of the semiconductor structure is reduced. In addition, after the adjacent word lines are disconnected, an additional process step needs to be performed to interconnect two word lines corresponding to the same transistor. In an interconnection fabrication procedure, alignment is difficult and the short circuit problem of the word lines is prone to occur. Therefore, how to improve the reliability of the word lines in the semiconductor structure needs to be urgently resolved.

Based on this, to resolve the foregoing problem, embodiments of the present disclosure provide a semiconductor structure and a fabrication method therefor.

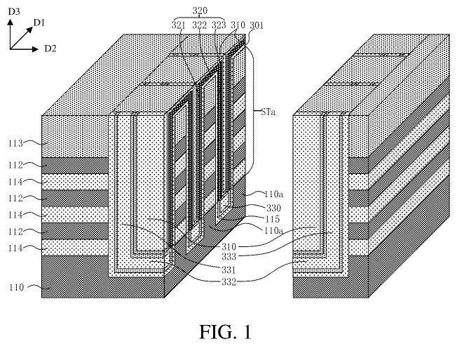

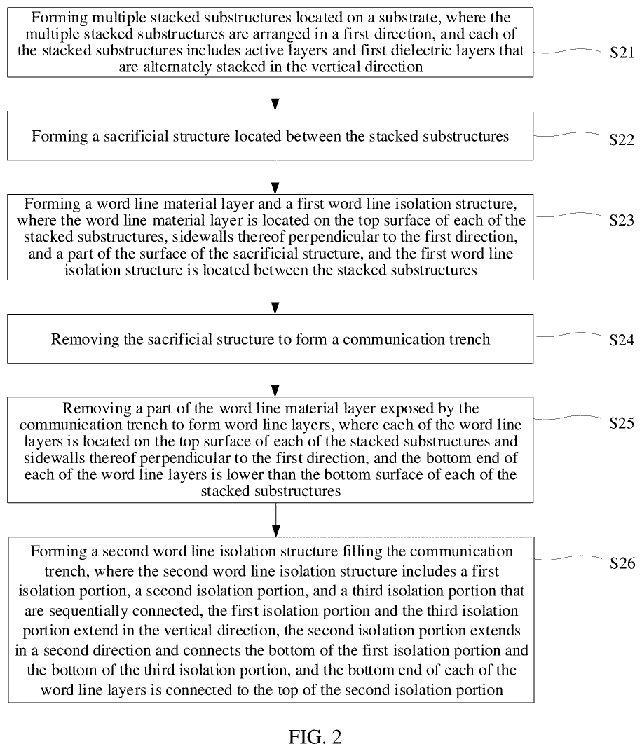

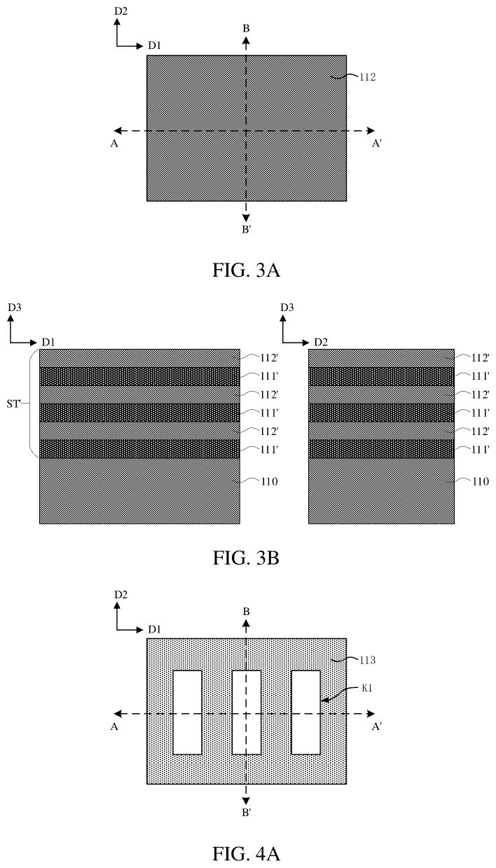

FIG. 1 is a three-dimensional schematic diagram of a part of a semiconductor structure according to an example embodiment. It may be understood that, for ease of illustrating an internal structure of the semiconductor structure, a partial cross-section of the semiconductor structure is shown in a form of dividing the three-dimensional semiconductor structure into two parts. In an actual structure, the two parts may be an integral structure. FIG. 2 is a flowchart of a fabrication method for a semiconductor structure according to an embodiment of the present disclosure. FIG. 3A to FIG. 13B are schematic top views and schematic cross-sectional views of a semiconductor structure in a fabrication procedure according to an embodiment of the present disclosure. In FIG. 1 and FIG. 3A to FIG. 13B, a first direction D1 and a second direction D2 are horizontal directions parallel to the plane in which a substrate 110 is located, and the first direction D1 intersects the second direction D2, for example, the first direction D1 may be perpendicular to the second direction D2. The vertical direction D3 is a direction that intersects the plane in which the substrate 110 is located, for example, the vertical direction D3 is perpendicular to the plane in which the substrate 110 is located.

As shown in FIG. 1, the semiconductor structure includes: multiple stacked substructures STa located on the substrate 110, where the multiple stacked substructures STa are arranged at intervals in the first direction D1, and each of the stacked substructures STa includes active layers 112 and first dielectric layers 114 that are alternately stacked in the vertical direction D3; word line layers 320, where each of the word line layers 320 is located on the top surface of each of the stacked substructures STa and sidewalls thereof perpendicular to the first direction D1, and the bottom end of each of the word line layers 320 is lower than the bottom surface of each of the stacked substructures STa; a first word line isolation structure 310, where the first word line isolation structure 310 is located between the stacked substructures STa; and a second word line isolation structure 330, where the second word line isolation structure 330 includes a first isolation portion 331, a second isolation portion 332, and a third isolation portion 333 that are sequentially connected, the first isolation portion 331 and the third isolation portion 333 extend in the vertical direction D3, the second isolation portion 332 extends in the second direction D2 and connects the bottom of the first isolation portion 331 and the bottom of the third isolation portion 333, and the bottom end of each of the word line layers 320 is connected to the top of the second isolation portion 332.

In the semiconductor structure provided in the present disclosure, in a first aspect, each of the word line layers covers the top surface and the sidewall of each of the stacked substructures as a whole. This can ensure interconnection between two parts of word line layers corresponding to the same transistor, avoid an open circuit of the word line layers, form a double-gate structure for each transistor active layer, and improve the gate control capability of the transistor. In a second aspect, the bottoms of adjacent ones of the word line layers are disconnected, and two parts of the first word line isolation structure and the second word line isolation structure are adopted to together isolate the adjacent ones of the word line layers, so that a short circuit between the word line layers can be avoided, and coupling between the word line layers can be effectively reduced. In a third aspect, the second word line isolation structure includes three parts that are sequentially connected, which are in a “U-shaped” morphology. Therefore, the consistency of width morphologies of the word line layers in the second direction can be increased, thereby improving the reliability of the semiconductor structure.

The material of the substrate 110 includes a semiconductor material, e.g., a single-element semiconductor material (e.g., silicon (Si) or germanium (Ge)), a III-V compound semiconductor material (e.g., gallium nitride (GaN), gallium arsenide (GaAs), or indium phosphide (InP)), a II-VI compound semiconductor material (e.g., zinc sulfide (ZnS), cadmium sulfide (CdS), or cadmium telluride (CdTe)), an organic semiconductor material, or another semiconductor material known in the art. The material of the active layers 112 may be monocrystalline silicon, polycrystalline silicon, germanium, silicon germanium, and an oxide semiconductor material (e.g., zinc tin oxide (ZnₓSn_{y}O, commonly known as “ZTO”), indium zinc oxide (InₓZn_{y}O, commonly known as “IZO”), zinc oxide (ZnₓO), indium gallium zinc oxide (InₓGa_{y}Zn_{z}O, commonly known as “IGZO”), indium gallium silicon oxide (InₓGa_{y}Si_{z}O, commonly known as “IGSO”), indium tin oxide (InₓSn_{y}O, commonly known as “ITO”), and one or more of other similar materials). The material of the first dielectric layers 114 is an insulating material such as silicon oxide, silicon nitride, silicon carbide, silicon carbide nitride, or silicon oxynitride.

In some embodiments, the material of the substrate 110 is monocrystalline silicon. The active layers 112 in the stacked substructures STa may be formed on the substrate 110 by adopting an epitaxial growth process, and the active layers 112 may be doped with dopant ions for serving as a source, a channel layer, and a drain of a transistor. The material of the first dielectric layers 114 is silicon oxide.

In some embodiments, each of the stacked substructures STa further includes a hard mask layer 113 located on the top of the active layers 112 and the first dielectric layers 114 that are alternately stacked. The hard mask layer 113 is configured to protect the active layer 112 or the first dielectric layer 114 on the top layer. The thickness of the hard mask layer 113 in the vertical direction D3 is greater than the thickness of each of the active layers 112 or the first dielectric layers 114 in the vertical direction D3.

In some embodiments, as shown in FIG. 1, each of the word line layers 320 is in an “inverted U”-shaped morphology in a cross section in the first direction D1 and the vertical direction D3. To be specific, each of the word line layers 320 includes a first word line portion 321, a second word line portion 322, and a third word line portion 323 that are sequentially connected, each of the first word line portion 321 and the third word line portion 323 is located on a sidewall of each of the stacked substructures STa perpendicular to the first direction D1, the second word line portion 322 connects the top of the first word line portion 321 and the top of the third word line portion 323, and the second word line portion 322 is located on the top surface of each of the stacked substructures STa. The word line layers 320 corresponding to different stacked substructures STa are disconnected at the bottom, and the first word line isolation structure 310 is sandwiched between adjacent ones of the word line layers 320.

In some embodiments, the top surface of the substrate 110 is in direct contact with one of the first dielectric layers 114, and the bottom end of each of the word line layers 320 is lower than the top surface of the first dielectric layer 114 at the bottom layer in each of the stacked substructures STa, and is flush with or higher than the top surface of each of the protrusion portions 110a of the substrate 110.

The word line layers 320 may be formed of conductive materials. The conductive materials may include one or more of the following: metals (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), cobalt (Co), and nickel (Ni)); alloys (e.g., a Co-based alloy, a Ti-based alloy, a Co-Ni-based alloy, and a Fe-Co-based alloy); conductive metal materials (e.g., a conductive metal nitride, a conductive metal silicide, a conductive metal carbide, and a conductive metal oxide); and conductive doped semiconductor materials (e.g., conductive doped polycrystalline silicon and conductive doped silicon germanium). For example, the materials of the word line layers 320 may be titanium nitride.

In some embodiments, as shown in FIG. 1, the first word line isolation structure 310 may be a single-layer structure or a multi-layer structure. For example, the first word line isolation structure 310 may be a double-layer structure formed by a silicon nitride layer and a silicon oxide layer, the silicon nitride layer conformally covers the surface of each of the word line layers 320, the silicon oxide layer is filled between silicon nitride layers, and the top surface of the first word line isolation structure 310 is higher than the top surface of each of the word line layers 320. It may be understood that the first word line isolation structure 310 may further include another low dielectric constant material, to reduce the parasitic capacitance between the word line layers 320.

In some embodiments, as shown in FIG. 1, the first isolation portion 331, the second isolation portion 332, and the third isolation portion 333 included in the second word line isolation structure 330 is in a “U”-shaped morphology in a cross section in the second direction D2 and the vertical direction D3. The second isolation portion 332 of the second word line isolation structure 330 is located below the first word line isolation structure 310 and each of the word line layers 320, and the top of the second word line isolation structure 330 is connected to the bottom end of the first word line isolation structure 310 and the bottom end of each of the word line layers 320. The width of the second word line isolation structure 330 in the first direction D1 is greater than the width of the first word line isolation structure 310 in the first direction D1. The second word line isolation structure 330 may be a single-layer structure or a multi-layer structure. For example, the second word line isolation structure 330 may be a double-layer structure formed by a silicon nitride layer and a silicon oxide layer. The silicon nitride layer of the second isolation portion 332 is in a ring-shaped morphology in a cross section in the first direction D1 and the vertical direction D3, and the silicon oxide layer is filled in the ring-shaped silicon nitride layer. The silicon nitride layer of the second isolation portion 332 is connected to the bottom end of each of the word line layers 320, and is connected to the bottom end of the silicon nitride layer of the first word line isolation structure 310.

In some embodiments, the width of the first word line isolation structure 310 in the second direction D2 is equal to the width of each of the word line layers 320 in the second direction D2, and the width of the second word line isolation structure 330 in the second direction D2 is equal to the width of each of the stacked substructures STa in the second direction D2. The first isolation portion 331 and the third isolation portion 333 are respectively located on two sides of the first word line portion 321 of each of the word line layers 320 in the second direction D2 and two sides of the third word line portion 323 in the second direction D2. The first isolation portion 331 and the third isolation portion 333 define the width of the first word line portion 321 and the width of the third word line portion 323 in the second direction D2. A spacing between the first isolation portion 331 and the third isolation portion 333 is equal to the width of the first word line isolation structure 310 in the second direction D2.

In some embodiments, the width of the first word line isolation structure 310 in the first direction D1 is equal to a spacing of adjacent ones of the word line layers 320 in the first direction D1, and the width of the second word line isolation structure 330 in the first direction D1 is equal to a spacing of adjacent ones of the stacked substructures STa in the first direction D1.

In some embodiments, the thickness of the first isolation portion 331 and the thickness of the third isolation portion 333 in the second direction D2 and the thickness of the second isolation portion 332 in the vertical direction D3 may be basically consistent.

In some embodiments, the substrate 110 includes protrusion portions 110a located under the stacked substructures STa, the second isolation portion 332 is located between the protrusion portions 110a, and the top surface of the second isolation portion 332 is lower than the top surface of each of the protrusion portions 110a. A groove between the protrusion portions 110a is formed on the surface of the substrate 110, so that the word line layers 320 penetrating deep into the substrate 110 can be formed, and the bottom end of each of the word line layers 320 is flush with or lower than the top surface of each of the protrusion portions 110a. In addition, each of the word line layers 320 is isolated from the substrate 110 by the second isolation portion 332, to reduce coupling between the word line layers 320 and leakage of a current between each of the word line layers 320 and the substrate 110 while ensuring the utilization of the word line layers 320. The ratio of an overlapped height between each of the word line layers 320 and each of the protrusion portions 110a in the vertical direction D3 to the height of each of the protrusion portions 110a in the vertical direction D3 ranges from 0 to 0.3.

In some embodiments, the semiconductor structure further includes a gate dielectric layer 301, where the gate dielectric layer 301 covers at least a sidewall of each of the active layers 112 perpendicular to the first direction D1; and a substrate protective layer 115, where the substrate protective layer 115 covers sidewalls and the bottom of a groove formed between adjacent ones of the protrusion portions 110a, and the substrate protective layer 115 is sandwiched between the second isolation portion 332 and the substrate 110; where the thickness of the substrate protective layer 115 is greater than the thickness of the gate dielectric layer 301, and the ratio of the thickness of the substrate protective layer 115 to the thickness of each of the first dielectric layers 114 ranges from 0.5 to 0.6.

In some embodiments, the gate dielectric layer 301 may be formed on the surface of each of the active layers 112 by adopting an in-situ steam generation (ISSG) process or a rapid thermal oxidation (RTO) process. Optionally, the gate dielectric layer 301 may be formed by adopting an atomic layer deposition process or a plasma vapor deposition process. The gate dielectric layer 301 may cover only the sidewall of each of the active layers 112 perpendicular to the first direction D1. In an example, the gate dielectric layer 301 further covers a sidewall of each of the first dielectric layers 114 perpendicular to the first direction D1 and a sidewall and the top surface of the hard mask layer 113. The gate dielectric layer 301 is sandwiched between each of the word line layers 320 and each of the stacked substructures STa, and the gate dielectric layer 301 may be further sandwiched between each of the word line layers 320 and the first word line isolation structure 310.

In some embodiments, the substrate protective layer 115 is formed synchronously with the first dielectric layers 114, and the material of the substrate protective layer 115 is the same as those of the first dielectric layers 114. The thickness of each of the first dielectric layers 114 in the vertical direction D3 is at most twice the thickness of the substrate protective layer 115 in the vertical direction D3.

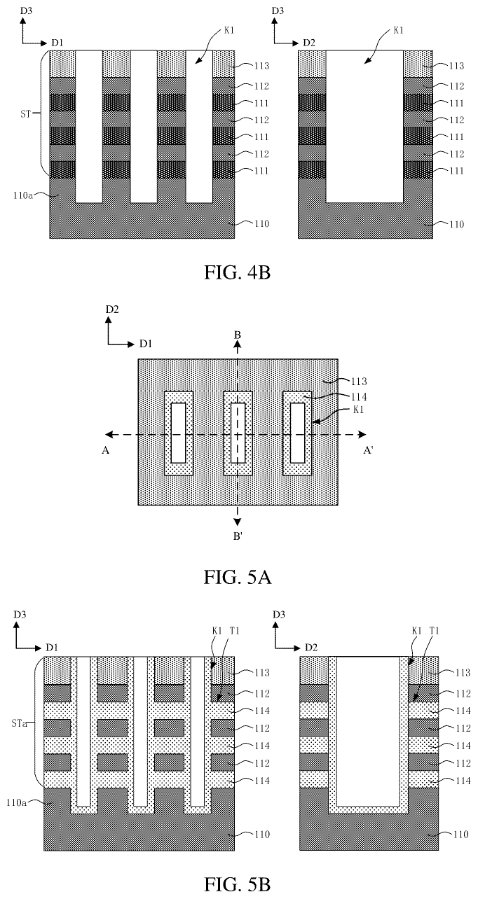

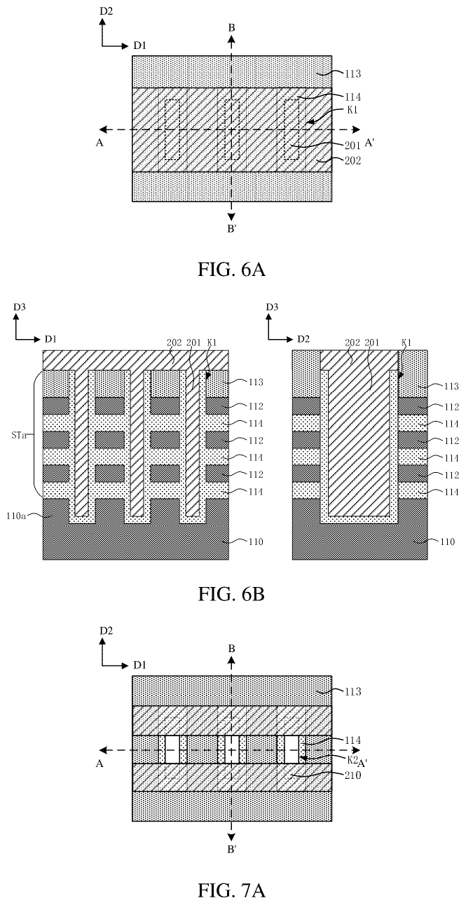

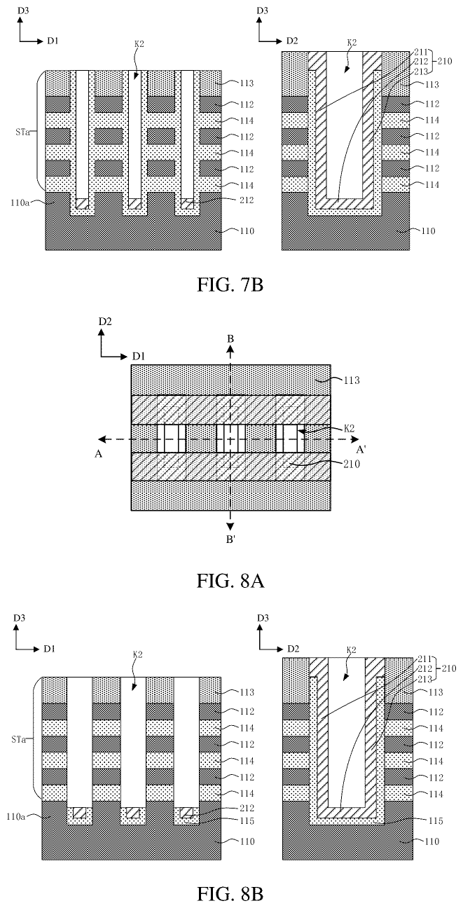

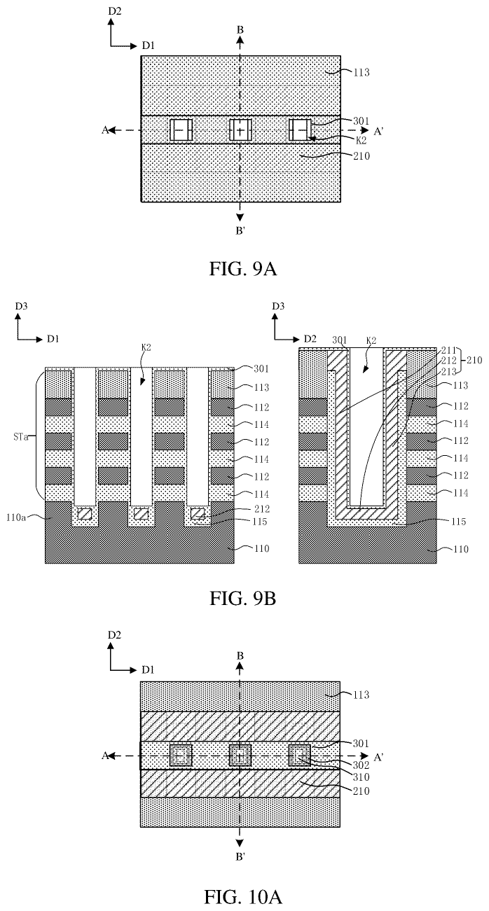

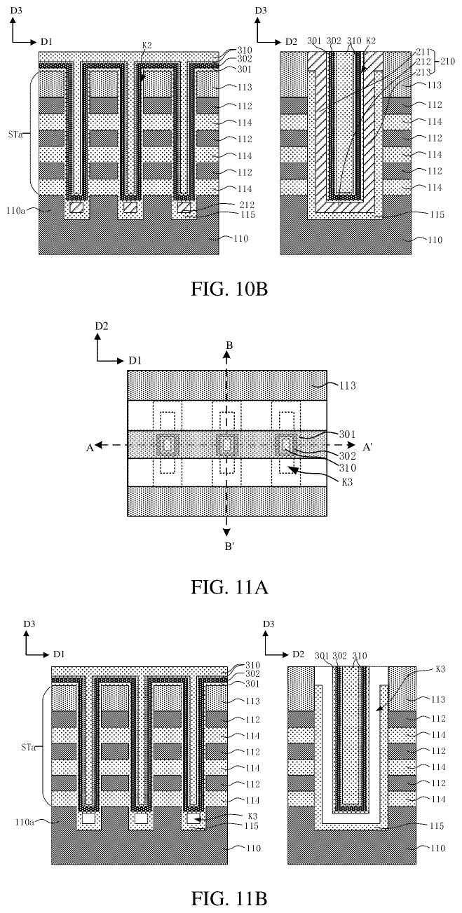

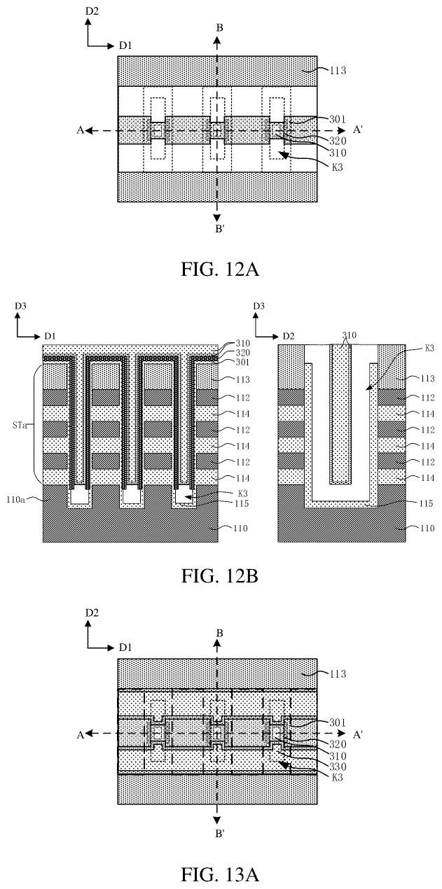

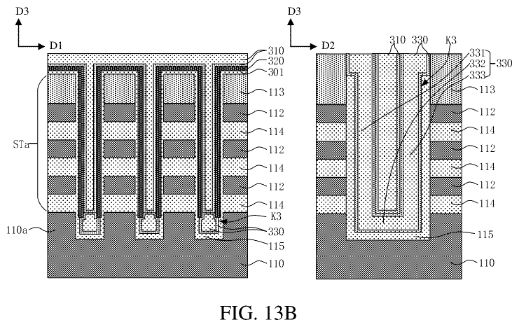

FIG. 2 is a flowchart of a fabrication method for a semiconductor structure according to an embodiment of the present disclosure. FIG. 3A, FIG. 4A, FIG. 5A, FIG. 6A, FIG. 7A, FIG. 8A, FIG. FIG. 9A, FIG. 10A, FIG. 11A, and FIG. 12A and FIG. 13A are schematic top views of a semiconductor structure in a fabrication procedure according to an embodiment of the present disclosure. FIG. 3B, FIG. 4B, FIG. 5B, FIG. 6B, FIG. 7B, FIG. 8B, FIG. 9B, FIG. 10B, FIG. 11B, and FIG. 12B and FIG. 13B are schematic cross-sectional views of a semiconductor structure in a fabrication procedure according to an embodiment of the present disclosure. With reference to FIG. 2, FIG. 3A to FIG. 13A, and FIG. 3B to FIG. 13B, the fabrication method for a semiconductor structure provided in the embodiments of the present disclosure is described below in detail. As shown in FIG. 2, the fabrication method includes at least the following steps.

In the step of S21, multiple stacked substructures located on a substrate are formed, where the multiple stacked substructures are arranged in a first direction, and each of the stacked substructures includes active layers and first dielectric layers that are alternately stacked in the vertical direction.

In the step of S22, a sacrificial structure located between the stacked substructures is formed.

In the step of S23, a word line material layer and a first word line isolation structure are formed, where the word line material layer is located on the top surface of each of the stacked substructures, sidewalls thereof perpendicular to the first direction, and a part of the surface of the sacrificial structure, and the first word line isolation structure is located between the stacked substructures.

In the step of S24, the sacrificial structure is removed to form a communication trench.

In the step of S25, a part of the word line material layer exposed by the communication trench are removed to form word line layers, where each of the word line layers is located on the top surface of each of the stacked substructures and sidewalls thereof perpendicular to the first direction, and the bottom end of each of the word line layers is lower than the bottom surface of each of the stacked substructures.

In the step of S26, a second word line isolation structure filling the communication trench is formed, where the second word line isolation structure includes a first isolation portion, a second isolation portion, and a third isolation portion that are sequentially connected, the first isolation portion and the third isolation portion extend in the vertical direction, the second isolation portion extends in a second direction and connects the bottom end of the first isolation portion and the bottom end of the third isolation portion, and the bottom end of each of the word line layers is connected to the top of the second isolation portion.

It should be understood that the steps shown in FIG. 2 are not exclusive, and another step may be performed before, after, or between any steps in the operations shown. The sequence of the steps shown in FIG. 2 may be adjusted according to an actual requirement.

In the fabrication method for a semiconductor structure provided in the present disclosure, in a first aspect, a position of the second word line isolation structure is defined in advance by occupation of the sacrificial structure, so that the consistency of a width morphology of each of the word line layers in the second direction can be precisely controlled. In a second aspect, the communication trench formed after the sacrificial structure is removed is utilized to disconnect a part of the word line material layer to form the word line layers. This can ensure that the bottoms of adjacent ones of the word line layers are disconnected, avoid a short circuit caused by residual of the word line material layers, and reduce damage to the active layers and the substrates. In a third aspect, two parts of the first word line isolation structure and the second word line isolation structure are adopted to together isolate the adjacent ones of the word line layers, so that a short circuit between the word line layers can be avoided, and coupling between the adjacent ones of the word line layers can be effectively reduced.

In some embodiments, after the substrate 110 is provided, that stacked substructures STa located on a substrate 110 are formed includes the steps as follows. As shown in FIG. 3A and FIG. 3B, stacked structures ST′ located on the substrate 110 are formed, where each of the stacked structures ST′ includes first semiconductor layers 111′ and second semiconductor layers 112′ that are alternately stacked. As shown in FIG. 4A and FIG. 4B, a part of the stacked structures ST′ and the substrate 110 are removed to form multiple first through-holes K1 and patterned stacked structures ST, where the multiple first through-holes K1 are arranged in the first direction D1 and run through the stacked structures ST′, and each of the patterned stacked structures ST is located between the first through-holes K1. As shown in FIG. 5A and FIG. 5B, a part of the first semiconductor layers 111 are removed through lateral etching along the first through-holes K1 to form first gap trenches T1, where the first gap trenches T1 are in communication with the multiple first through-holes K1; and first dielectric layers 114 are deposited to form the stacked substructures STa, where the first dielectric layers 114 fill the first gap trenches T1 and cover sidewalls of the multiple first through-holes K1.

In some embodiments, as shown in FIG. 3A and FIG. 3B, the left figure in FIG. 3B is a schematic cross-sectional diagram along an AA′ cross section in FIG. 3A, and the right figure in FIG. 3B is a schematic cross-sectional diagram along a BB′ cross section in FIG. 3A. The materials of the first semiconductor layers 111′ and the materials of the second semiconductor layers 112′ are different. The materials of the second semiconductor layers 112′ may be monocrystalline silicon, polycrystalline silicon, germanium, silicon germanium, and oxide semiconductor materials (e.g., zinc tin oxide (ZnₓSn_{y}O, commonly known as “ZTO”), indium zinc oxide (InₓZn_{y}O, commonly known as “IZO”), zinc oxide (ZnₓO), indium gallium zinc oxide (InₓGa_{y}Zn_{z}O, commonly known as “IGZO”), indium gallium silicon oxide (InₓGa_{y}Si_{z}O, commonly known as “IGSO”), and one or more of other similar materials). For example, the materials of the second semiconductor layers 112′ are monocrystalline silicon, and the materials of the first semiconductor layers 111′ are silicon germanium. The first semiconductor layers 111′ and the second semiconductor layers 112′ may be sequentially formed alternately by adopting an epitaxial growth process or a deposition process. The deposition process may include chemical vapor deposition, an atomic layer deposition process, plasma enhanced chemical vapor deposition, physical vapor deposition, plasma enhanced chemical vapor deposition, low pressure chemical vapor deposition, or the like.

In some embodiments, as shown in FIG. 4A and FIG. 4B, the left figure in FIG. 4B is a schematic cross-sectional diagram along an AA′ cross section in FIG. 4A, and the right figure in FIG. 4B is a schematic cross-sectional diagram along a BB′ cross section in FIG. 4A. The patterned hard mask layer 113 is formed on each of the stacked structures ST′, the hard mask layer 113 serves as a mask to etch each of the stacked structures ST′ to obtain the multiple first through-holes K1, and the multiple first through-holes K1 separate the stacked structure ST′ into the patterned stacked structures ST arranged at intervals in the first direction D1. The first through-holes K1 penetrate deep into the substrate 110, that is, the bottom surface of each of the first through-holes K1 is lower than the top surface of the substrate 110. Protrusion portions 110a and a groove between the protrusion portions 110a are formed on the surface of the substrate 110. The multiple first through-holes K1 separate the second semiconductor layers 112′ into patterned second semiconductor layers, which serve as active layers 112. The multiple first through-holes K1 separate the first semiconductor layers 111′ into patterned first semiconductor layers 111.

In some embodiments, as shown in FIG. 5A and FIG. 5B, the left figure in FIG. 5B is a schematic cross-sectional diagram along an AA′ cross section in FIG. 5A, and the right figure in FIG. 5B is a schematic cross-sectional diagram along a BB′ cross section in FIG. 5A. The patterned first semiconductor layers 111 may be removed by adopting a wet etching process to form the first gap trench T1 between adjacent ones of the active layers 112 in the vertical direction D3. The first dielectric layers 114 are formed by adopting a deposition process to completely fill the first gap trenches T1. The ratio of the thickness of the first dielectric layer 114 covering an inner wall of the groove between the protrusion portions 110a to the height of each of the first gap trenches T1 in the vertical direction D3 ranges from 0.5 to 0.6. The stacked substructures STa include the active layers 112 and the first dielectric layers 114 that are alternately stacked in the vertical direction D3.

In some embodiments, when the first through-holes K1 are formed, second through-holes are further formed, and the second through-holes may extend in the first direction and run through the stacked structures in the vertical direction. Two of the second through-holes may be located on two sides of each of the multiple first through-holes in the second direction, to remove the first dielectric layers on two sides of each of the patterned stacked structures ST while forming the first gap trenches T1. Along the second through-holes, a part of the active layers 112 may be further removed to form bit line trenches, to form, in the bit line trenches, bit line structures connected to end portions of the active layers 112. The bit line structures may extend in the first direction, and multiple ones of the bit line structures may be arranged at intervals in the vertical direction.

In some embodiments, as shown in FIG. 6A, FIG. 6B, FIG. 7A, and FIG. 7B, that a sacrificial structure 210 located between the stacked substructures STa is formed includes the steps as follows. Vertical sacrificial portions 201 filling the multiple first through-holes K1 are formed; and a part of each of the vertical sacrificial portions 201 are removed to form the sacrificial structure 210, where the sacrificial structure 210 includes a first sacrificial portion 211, a second sacrificial portion 212, and a third sacrificial portion 213 that are sequentially connected, the first sacrificial portion 211 and the third sacrificial portion 213 extend in the vertical direction D3, the second sacrificial portion 212 extends in the second direction D2 and connects the bottom end of the first sacrificial portion 211 and the bottom end of the third sacrificial portion 213, and the top surface of the second sacrificial portion 212 is lower than the bottom surface of each of the stacked substructures STa.

In some embodiments, as shown in FIG. 6A and FIG. 6B, the left figure in FIG. 6B is a schematic cross-sectional diagram along an AA′ cross section in FIG. 6A, and the right figure in FIG. 6B is a schematic cross-sectional diagram along a BB′ cross section in FIG. 6A. Sacrificial materials are filled, to form the vertical sacrificial portions 201 and a horizontal sacrificial portion 202 in the multiple first through-holes K1. The horizontal sacrificial portion 202 connects the top surfaces of the multiple ones of the vertical sacrificial portions 201 arranged at intervals in the first direction D1. The top surface of each of the vertical sacrificial portions 201 is flush with the top surface of each of the stacked substructures STa. In another example, the horizontal sacrificial portion 202 may not be formed. The sacrificial materials may be materials having a high etching selectivity ratio with the active layers 112 and the first dielectric layers 114, such as polycrystalline silicon, a photoresist, and silicon carbide.

In some embodiments, as shown in FIG. 7A and FIG. 7B, the left figure in FIG. 7B is a schematic cross-sectional diagram along an AA′ cross section in FIG. 7A, and the right figure in FIG. 7B is a schematic cross-sectional diagram along a BB′ cross section in FIG. 7A. A word line trench K2 is enclosed by the first sacrificial portion 211, the second sacrificial portion 212, and the third sacrificial portion 213. That a word line material layer 302 and a first word line isolation structure 310 are formed includes the steps as follows. As shown in FIG. 8A and FIG. 8B, a part of the first dielectric layers 114 that are located on sidewalls of the first through-holes K1 and that are exposed by the word line trench K2 are removed. As shown in FIG. 9A and FIG. 9B, a gate dielectric layer 301 on a sidewall of each of the active layers 112 exposed by the word line trench K2 is formed. As shown in FIG. 10A and FIG. 10B, the word line material layer 302 conformally covering an inner wall of the word line trench K2 is formed, and the first word line isolation structure 310 is filled.

In some embodiments, as shown in FIG. 8A and FIG. 8B, the left figure in FIG. 8B is a schematic cross-sectional diagram along an AA′ cross section in FIG. 8A, and the right figure in FIG. 8B is a schematic cross-sectional diagram along a BB′ cross section in FIG. 8A. After a part of each of the vertical sacrificial portions 201 and the first dielectric layers 114 on the sidewalls of the stacked substructures STa are removed, the second sacrificial portion 212 and a substrate protective layer 115 that are located in the groove between the protrusion portions 110a are retained. The top surface of the second sacrificial portion 212 is flush with the top surface of the substrate protective layer 115, and is lower than the top surface of each of the protrusion portions 110a.

In some embodiments, as shown in FIG. 9A and FIG. 9B, the left figure in FIG. 9B is a schematic cross-sectional diagram along an AA′ cross section in FIG. 9A, and the right figure in FIG. 9B is a schematic cross-sectional diagram along a BB′ cross section in FIG. 9A. The gate dielectric layer 301 may be formed by adopting a deposition process. The gate dielectric layer 301 covers a sidewall and the top surface of each of the stacked substructures STa exposed by the word line trench K2, and the gate dielectric layer 301 further covers the top surface of the second sacrificial portion 212. The thickness of the gate dielectric layer 301 is less than the thickness of each of the first dielectric layers 114. By removing a part of the first dielectric layers 114, the gate dielectric layer 301 is reformed, so that the thickness and the quality of the gate dielectric layer 301 can be ensured.

In some embodiments, as shown in FIG. 10A and FIG. 10B, the left figure in FIG. 10B is a schematic cross-sectional diagram along an AA′ cross section in FIG. 10A, and the right figure in FIG. 10B is a schematic cross-sectional diagram along a BB′ cross section in FIG. 10A. The first word line isolation structure 310 is filled after the word line material layers 302 are conformally deposited. The first word line isolation structure 310 may be a double-layer structure formed by a silicon nitride layer and a silicon oxide layer, the silicon nitride layer conformally covers the surface of the word line material layer 302, the silicon oxide layer is filled between silicon nitride layers, and the top surface of the silicon oxide layer is higher than the top surface of the word line material layer 302.

In some embodiments, that the sacrificial structure 210 is removed includes the steps as follows. As shown in FIG. 10A and FIG. 10B, after the first word line isolation structure 310 is formed, planarization processing is performed to remove the gate dielectric layer 301 located at the top surface of the sacrificial structure 210, to expose the top surface of the first sacrificial portion 211 and the top surface of the third sacrificial portion 213. As shown in FIG. 11A and FIG. 11B, the left figure in FIG. 11B is a schematic cross-sectional diagram along an AA′ cross section in FIG. 11A, and the right figure in FIG. 11B is a schematic cross-sectional diagram along a BB′ cross section in FIG. 11A. The first sacrificial portion 211, the second sacrificial portion 212, and the third sacrificial portion 213 are removed by adopting a wet etching process, to form a communication trench K3.

In some embodiments, as shown in FIG. 12A and FIG. 12B, the left figure in FIG. 12B is a schematic cross-sectional diagram along an AA′ cross section in FIG. 12A, and the right figure in FIG. 12B is a schematic cross-sectional diagram along a BB′ cross section in FIG. 12A. A part of the word line material layer 302 exposed by the communication trench K3 are removed to form word line layers 320, where each of the word line layers 320 is located on the top surface of each of the stacked substructures STa and sidewalls thereof perpendicular to the first direction D1, and the bottom end of each of the word line layers 320 is lower than the bottom surface of each of the stacked substructures STa; and a second word line isolation structure 330 filling the communication trench K3 is formed, where the second word line isolation structure 330 includes a first isolation portion 331, a second isolation portion 332, and a third isolation portion 333 that are sequentially connected, the first isolation portion 331 and the third isolation portion 333 extend in the vertical direction D3, the second isolation portion 332 extends in the second direction D2 and connects the bottom end of the first isolation portion 331 and the bottom end of the third isolation portion 333, and the bottom end of each of the word line layers 320 is connected to the top of the second isolation portion 332.

In some embodiments, as shown in FIG. 13A and FIG. 13B, the left figure in FIG. 13B is a schematic cross-sectional diagram along an AA′ cross section in FIG. 13A, and the right figure in FIG. 13B is a schematic cross-sectional diagram along a BB′ cross section in FIG. 13A. A second word line isolation structure 330 filling the communication trench K3 is formed, where the second word line isolation structure 330 includes a first isolation portion 331, a second isolation portion 332, and a third isolation portion 333 that are sequentially connected, the first isolation portion 331 and the third isolation portion 333 extend in the vertical direction D3, the second isolation portion 332 extends in the second direction D2 and connects the bottom end of the first isolation portion 331 and the bottom end of the third isolation portion 333, and the bottom end of each of the word line layers 320 is connected to the top of the second isolation portion 332.

In some embodiments, the semiconductor structure includes a memory. The memory may be a dynamic random access memory, for example, may be a three-dimensional dynamic random access memory. Alternatively, the memory may be a memory known in the art, e.g., a phase change memory or a ferroelectric memory.

Various semiconductor structures shown in the specific implementations may be utilized in electronic devices with a storage function. Each of the electronic devices may be a terminal device, e.g., a mobile phone, a tablet computer, or a mart wristband, or may be a personal computer (PC), a server, or a workstation. The storage function in the electronic devices may be implemented by the following memory: a dynamic random access memory (DRAM), a ferroelectric random access memory (FRAM), a phase change memory (PCM), a magnetic random access memory (MRAM), or a resistive random access memory (RRAM).

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

1. A semiconductor structure, comprising:
a plurality of stacked substructures located on a substrate, the plurality of stacked substructures being arranged at intervals in a first direction, and each of the stacked substructures comprising active layers and first dielectric layers that are alternately stacked in a vertical direction;
word line layers, each of the word line layers being located on a top surface of each of the stacked substructures and sidewalls thereof perpendicular to the first direction, and a bottom end of each of the word line layers being lower than a bottom surface of the stacked substructures;
a first word line isolation structure, the first word line isolation structure being located between the stacked substructures; and
a second word line isolation structure, the second word line isolation structure comprising a first isolation portion, a second isolation portion, and a third isolation portion that are sequentially connected, the first isolation portion and the third isolation portion extending in the vertical direction, the second isolation portion extending in a second direction and connecting a bottom of the first isolation portion and a bottom of the third isolation portion, and the bottom end of each of the word line layers being connected to a top of the second isolation portion.

2. The semiconductor structure according to claim 1, wherein the substrate comprises protrusion portions located under the stacked substructures, the second isolation portion is located between the protrusion portions, and the top surface of the second isolation portion is lower than a top surface of each of the protrusion portions.

3. The semiconductor structure according to claim 2, further comprising:
a gate dielectric layer, wherein the gate dielectric layer covers a sidewall of each of the active layers perpendicular to the first direction; and
a substrate protective layer, wherein the substrate protective layer covers sidewalls and a bottom of a groove formed between adjacent ones of the protrusion portions, and the substrate protective layer is sandwiched between the second isolation portion and the substrate; wherein
a thickness of the substrate protective layer is greater than a thickness of the gate dielectric layer, and a ratio of the thickness of the substrate protective layer to a thickness of each of the first dielectric layers ranges from 0.5 to 0.6.

4. The semiconductor structure according to claim 1, wherein a width of the first word line isolation structure in the second direction is equal to a width of each of the word line layers in the second direction, and a width of the second word line isolation structure in the second direction is equal to a width of the each of stacked substructures in the second direction.

5. The semiconductor structure according to claim 1, wherein a width of the first word line isolation structure in the first direction is equal to a spacing of adjacent ones of the word line layers in the first direction, and a width of the second word line isolation structure in the first direction is equal to a spacing of adjacent ones of the stacked substructures in the first direction.

6. The semiconductor structure according to claim 1, wherein each of the word line layers is in an inverted U-shaped morphology in a cross section in the first direction and the vertical direction.

7. The semiconductor structure according to claim 6, wherein each of the word line layers comprises a first word line portion, a second word line portion, and a third word line portion that are sequentially connected, each of the first word line portion and the third word line portion is located on a sidewall of each of the stacked substructures perpendicular to the first direction, the second word line portion connects a top of the first word line portion and a top of the third word line portion, and the second word line portion is located on the top surface of each of the stacked substructures.

8. The semiconductor structure according to claim 3, wherein materials of the substrate protective layer and the first dielectric layers are the same, and a thickness of each of the first dielectric layers in the vertical direction is at most twice a thickness of the substrate protective layer in the vertical direction.

9. A fabrication method for a semiconductor structure, comprising:
forming a plurality of stacked substructures located on a substrate, the plurality of stacked substructures being arranged in a first direction, and each of the stacked substructures comprising active layers and first dielectric layers that are alternately stacked in a vertical direction;
forming a sacrificial structure located between the stacked substructures;
forming a word line material layer and a first word line isolation structure, the word line material layer being located on a top surface of each of the stacked substructures, sidewalls thereof perpendicular to the first direction, and a part of a surface of the sacrificial structure, and the first word line isolation structure being located between the stacked substructures;
removing the sacrificial structure to form a communication trench;
removing a part of the word line material layer exposed by the communication trench to form word line layers, each of the word line layers being located on a top surface of each of the stacked substructures and sidewalls thereof perpendicular to the first direction, and a bottom end of each of the word line layers being lower than a bottom surface of each of the stacked substructures; and
forming a second word line isolation structure filling the communication trench, the second word line isolation structure comprising a first isolation portion, a second isolation portion, and a third isolation portion that are sequentially connected, the first isolation portion and the third isolation portion extending in the vertical direction, the second isolation portion extending in a second direction and connecting a bottom of the first isolation portion and a bottom of the third isolation portion, and the bottom end of each of the word line layers being connected to a top of the second isolation portion.

10. The fabrication method according to claim 9, wherein the forming stacked substructures located on a substrate comprises:
forming stacked structures located on the substrate, wherein each of the stacked structures comprises first semiconductor layers and second semiconductor layers that are alternately stacked;
removing a part of the stacked structures and the substrate to form a plurality of first through-holes and patterned stacked structures, wherein the plurality of first through-holes are arranged in the first direction and run through the stacked structures, and each of the patterned stacked structures is located between the first through-holes;
removing a part of the first semiconductor layers through lateral etching along the first through-holes to form first gap trenches, wherein the first gap trenches are in communication with the plurality of first through-holes; and
depositing first dielectric layers to form the stacked substructures, wherein the first dielectric layers fill the first gap trenches and cover sidewalls of the plurality of first through-holes.

11. The fabrication method according to claim 10, wherein the forming a sacrificial structure located between the stacked substructures comprises:
forming vertical sacrificial portions filling the plurality of first through-holes; and
removing a part of each of the vertical sacrificial portions to form the sacrificial structure, wherein the sacrificial structure comprises a first sacrificial portion, a second sacrificial portion, and a third sacrificial portion that are sequentially connected, the first sacrificial portion and the third sacrificial portion extend in the vertical direction, the second sacrificial portion extends in the second direction and connects a bottom of the first sacrificial portion and a bottom of the third sacrificial portion, and a top surface of the second sacrificial portion is lower than the bottom surface of each of the stacked substructures.

12. The fabrication method according to claim 11, wherein a word line trench is enclosed by the first sacrificial portion, the second sacrificial portion, and the third sacrificial portion; and the forming a word line material layer and a first word line isolation structure comprises:
removing a part of the first dielectric layers that are located on sidewalls of the first through-holes and that are exposed by the word line trench;
forming a gate dielectric layer on a sidewall of each of the active layers exposed by the word line trench; and
forming the word line material layer conformally covering an inner wall of the word line trench, and filling the first word line isolation structure.

13. The fabrication method according to claim 11, wherein the removing the sacrificial structure comprises:
performing planarization processing to expose a top surface of the first sacrificial portion and a top surface of the third sacrificial portion; and
removing the first sacrificial portion, the second sacrificial portion, and the third sacrificial portion by adopting a wet etching process.

14. The fabrication method according to claim 10, wherein a bottom surface of each of the first through-holes is lower than a top surface of the substrate.

15. The fabrication method according to claim 11, wherein during forming vertical sacrificial portions filling the plurality of first through-holes, the method further comprises:
forming a horizontal sacrificial portion, wherein the horizontal sacrificial portion connects top surfaces of a plurality of ones of the vertical sacrificial portions arranged at intervals in the first direction.

16. The fabrication method according to claim 12, wherein the substrate comprises protrusion portions located under the stacked substructures; and when a part of each of the vertical sacrificial portions and a part of the first dielectric layers are removed, a second sacrificial portion and a substrate protective layer that are located in a groove between the protrusion portions are retained; and a top surface of the second sacrificial portion is flush with a top surface of the substrate protective layer, and is lower than a top surface of each of the protrusion portions.
